(19) United States
(12) Patent Application Publication
(10) Pub. No.: US 2021/0252620 A1
(43) Pub. Date: Aug. 19, 2021

(54) TRANSFER AND BONDING METHOD USING LASER

(71) Applicant: Electronics and Telecommunications Research Institute, Daejeon (KR)

(72) Inventors: KWANG-SEONG CHOI, Daejeon (KR); Yong Sung EOM, Daejeon (KR); Jiho JOO, Sejong-si (KR); Seok-Hwan MOON, Daejeon (KR); Ho-Gyeong YUN, Seoul (KR); Ki Seok JANG, Sejong-si (KR); GWANG-MUN CHOI, Daejeon (KR)

(73) Assignee: Electronics and Telecommunications Research Institute, Daejeon (KR)

(21) Appl. No.: 17/178,571

(22) Filed: Feb. 18, 2021

(30) Foreign Application Priority Data
Feb. 19, 2020 (KR) 10-2020-0020382

(51) Int. Cl. B23K 1/005; B23K 35/36

(52) U.S. Cl. CPC B23K 1/0056; B23K 2101/40; B23K 35/3613

(57) ABSTRACT

The present disclosure relates to a transfer and bonding method using a laser. As a plurality of devices or packages are simultaneously transferred onto a substrate from a transfer tape by irradiating a top surface of the transfer tape with a first laser, and the plurality of transferred devices or packages are simultaneously bonded to pads of a substrate by irradiating a top surface of the devices or packages with a second laser, a speed of a transfer and bonding process may be extremely maximized.

### CROSS-REFERENCE TO RELATED APPLICATIONS

This U.S. non-provisional patent application claims priority under 35 U.S.C. § 119 of Korean Patent Application No. 10-2020-0020382, filed on Feb. 19, 2020, the entire contents of which are hereby incorporated by reference.

### BACKGROUND

The present disclosure herein relates to a transfer and bonding method using a laser, which may extremely maximize a speed of a transfer and bonding process because a plurality of objects to be bonded are simultaneously transferred onto a substrate from a transfer tape by irradiating the transfer tape with a first laser, and the plurality of transferred objects to be bonded are simultaneously bonded to pads disposed on the substrate by irradiating the objects to be bonded with a second laser.

When a semiconductor, a sensor, LED, and a communication device or package, which are manufactured in a wafer, are transferred from the manufacturing wafer thereof or a manufacturing panel thereof to another substrate, a pick and place process using a pick-up too, an up tool, or a place tool is typically used. However, in recent years, the number of devices or packages to be bonded onto one substrate extremely increases, a process speed of the typical technology may not satisfy a production rate demanded in the market.

### SUMMARY

The present disclosure provides a transfer and bonding method using a laser.

The object of the present invention is not limited to the aforesaid, but other objects not described herein will be clearly understood by those skilled in the art from descriptions below.

An embodiment of the inventive concept provides a transfer and bonding method using a laser, including: providing a substrate including a pad; forming a bonding part on the substrate to cover the pad; aligning a transfer tape including an object to be bonded on the boding part; transferring the object to be bonded onto the bonding part by irradiating a top surface of the transfer tape with a first laser; and bonding the bonding part with the object to be bonded by irradiating a top surface of the object to be bonded with a second laser.

In an embodiment, the bonding part may include solder particles.

In an embodiment, the bonding of the bonding part with the object to be bonded may include: bonding an upper portion of each of the solder particles with a pad of the object to be bonded; and bonding a lower portion of each of the solder particles with a pad of the substrate.

In an embodiment, the bonding of the upper portion of each of the solder particles with the pad of the object to be bonded may include forming an intermetallic compound by the upper portion of the solder particle and the pad of the object to be bonded, and the bonding of the lower portion of each of the solder particles with the pad of the substrate may include forming an intermetallic compound by the lower portion of the solder particle and the pad of the substrate.

In an embodiment, the bonding of the bonding part with the object to be bonded may include removing an oxide layer of each of the solder particles by irradiating the object to be bonded with the second laser.

In an embodiment, one area of the transfer tape, which overlaps the object to be bonded, may be irradiated with the first laser, and a top surface of the substrate, to which the object to be bonded is transferred, may be irradiated with the second laser.

In an embodiment, the transferring of the object to be bonded may include reducing a contact area between the transfer tape and the object to be bonded by irradiating the transfer tape with the first laser so that one surface of the transfer tape, which is adjacent to the object to be bonded, swells.

In an embodiment, the bonding of the bonding part with the object to be bonded may include electrically connecting a pad of the object to be bonded and the pad of the substrate.

In an embodiment, the bonding part may include one of a polymer material, a reducing agent, and a curing agent.

In an embodiment, the polymer material may include one of epoxy resin, phenoxy resin, bismaleimide, unsaturated polyester, urethane, urea, phenol-formaldehyde, vulcanized rubber, melamine resin, polyimide, epoxy novolac resin, cyanate ester, silicone resin, and acrylic resin.

In an embodiment, the curing agent may include one of aliphatic amine, aromatic amine, cycloaliphatic amine, phenalkamine, imidazole, carboxylic acid, anhydride, polyamide-based hardners, phenolic curing agents, and waterborne curing agents.

In an embodiment, the transfer tape may include one of poly(methyl methacrylate)(PMMA), poly(N-vinylcarbazole), gelatin films, PEN, PET, PTFE (Teflon), and polyimide.

In an embodiment, the transfer and bonding method may further include curing the bonding part and the object to be bonded after bonded to each other.

In an embodiment, the bonding the bonding part with the object to be bonded by irradiating the top surface of the object to be bonded with the second laser may be performed before the transferring the object to be bonded onto the bonding part by irradiating the top surface of the transfer tape with the first laser.

In an embodiment, the transferring the object to be bonded onto the bonding part by irradiating the top surface of the transfer tape with the first laser may include: irradiating the top surface of the transfer tape with the first laser, and removing the transfer tape. Here, the bonding the bonding part with the object to be bonded by irradiating the top surface of the object to be bonded with the second laser may be performed after the irradiating the top surface of the transfer tape with the first laser, and before the removing the transfer tape.

In an embodiment of the inventive concept, a transfer and bonding method using a laser includes: providing a substrate including a pad; forming a bonding part on the substrate to cover the pad; aligning a transfer tape including an object to be bonded on the boding part; transferring the object to be bonded onto the bonding part by irradiating a top surface of the transfer tape with a first laser; and bonding the bonding part with the object to be bonded by irradiating a top surface of the bonding part with a second laser. Here, a pad of the object to be bonded or the pad disposed on the substrate includes a solder formed thereon, and wherein the bonding of the bonding part with the object to be bonded comprises removing an oxide layer of each of the solder particles by irradiating the solder particles with the second laser.

In an embodiment, the transferring of the object to be bonded may include reducing a contact area between the transfer tape and the object to be bonded by irradiating the transfer tape with the first laser so that one surface of the transfer tape, which is adjacent to the object to be bonded, swells.

In an embodiment, one area of the transfer tape, which overlaps the object to be bonded, may be irradiated with the first laser, and a top surface of the substrate, to which the object to be bonded is transferred, may be irradiated with the second laser.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a flowchart representing a transfer and bonding method using a laser according to an embodiment of the inventive concept;

FIGS. 2 to 4 are process views illustrating each process of the transfer and bonding method using a laser according to an embodiment;

FIGS. 5A, 5B, and 5C are process views illustrating each process of transferring the bonding target object to the substrate according to an embodiment of the inventive concept;

FIGS. 6A and 6B are process views illustrating each process of bonding a bonding part with an object to be bonded according to an embodiment of the inventive concept;

FIGS. 7, 8A, and 8B are process views illustrating a transfer and bonding method according to a modified embodiment of the inventive concept; and

FIGS. 9, 10A, and 10B are process views illustrating a transfer and bonding method according to another modified embodiment of the inventive concept.

### DETAILED DESCRIPTION

Advantages and features of the present invention, and implementation methods thereof will be clarified through following embodiments described with reference to the accompanying drawings. The present invention may, however, be embodied in many different forms and should not be construed as being limited to the embodiments set forth herein. Rather, these embodiments are provided so that this disclosure will be thorough and complete, and will fully convey the concept of the invention to those skilled in the art. Further, the present invention is only defined by scopes of claims. Like reference numerals refer to like elements throughout.

In the following description, the technical terms are used only for explaining a specific exemplary embodiment while not limiting the present disclosure. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiment in the detailed description will be described with sectional views as ideal exemplary views of the present invention. Also, in the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. Areas exemplified in the drawings have general properties, and are used to illustrate a specific shape of a semiconductor package region. Thus, this should not be construed as limited to the scope of the present invention.

Unless terms used in embodiments of the present invention are differently defined, the terms may be construed as meanings that are commonly known to a person skilled in the art.

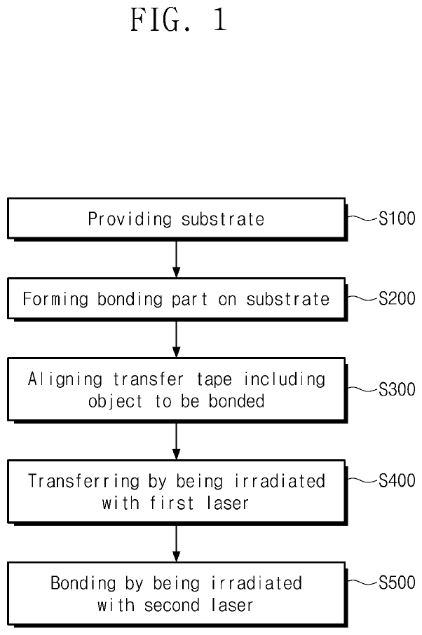

FIG. 1 is a flowchart representing a transfer and bonding method using a laser according to an embodiment of the inventive concept.

Referring to FIG. 1, a transfer and bonding method using a laser according to an embodiment of the inventive concept may include: a process S100 of providing a substrate including a pad; a process S200 of forming a bonding part on the substrate; a process S300 of aligning a transfer tape including an object to be bonded (hereinafter, referred to as a bonding target object) on the bonding part, a process S400 of transferring the bonding target object on the bonding part by irradiating a top surface of the transfer tape with a first laser; and a process S500 of bonding the bonding part with the bonding target object by irradiating a top surface of the bonding target object with a second laser.

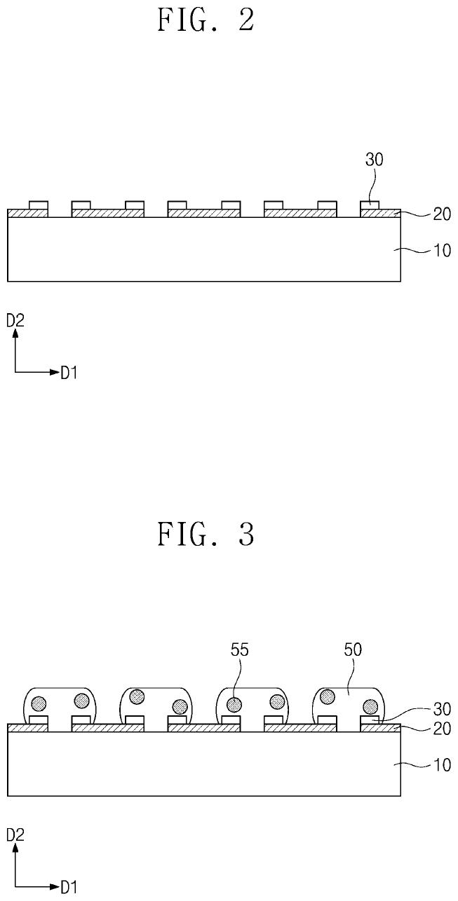

FIGS. 2 to 4 are process views illustrating each process of the transfer and bonding method using a laser according to an embodiment.

Referring to FIGS. 1 and 2, a substrate 10 may be provided in the process S100. The substrate 10 may include a printed circuit board (PCB). A pattern 20 may be disposed on a top surface of the substrate 10, and a pad 30 may be disposed on a top surface of the pattern 20. The pad 30 may be provided in plurality. The pads 30 may be spaced apart from each other in a first direction D1.

Each of the pattern 20 and the pad 30 may include a conductive material. Specifically, each of the pattern 20 and the pad 30 may include copper (Cu) or aluminum (Al). Through the pattern 20 and the pad 30, external components of the substrate 10 may be electrically connected to internal circuits (not shown) of the substrate 10. In this specification, a term “connected” may include all of a term “directly connected” and a term “indirectly connected through another component”

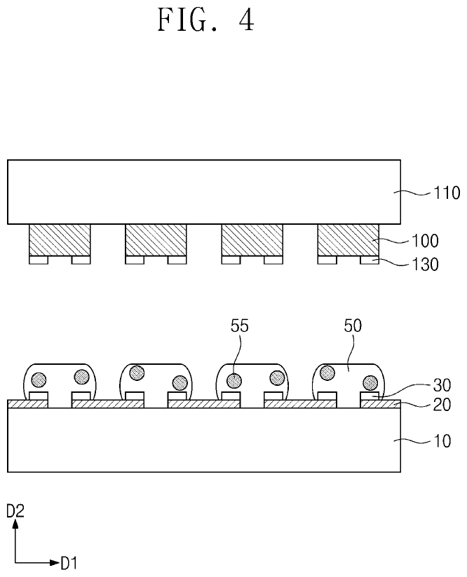

Referring to FIGS. 1 and 3, a bonding part 50 may be formed on the substrate 10 in the process S200. The bonding part 50 may be formed on a portion or a whole of the top surface of the substrate 10. Specifically, the bonding part 50 may be formed on a portion on the substrate 10, to which the bonding target object is bonded.

The bonding part 50 may include solder particles 55. The solder particles 55 may be provided in plurality. Specifically, the number of the solder particles 55 may be equal to or greater than that of the pads 30 of the substrate 10.

The bonding part 50 may include one of a polymer material, a reducing agent, and a curing agent. The bonding part 50 may have a film shape or a paste shape.

The polymer material may include one of epoxy resin, phenoxy resin, bismaleimide, unsaturated polyester, urethane, urea, phenol-formaldehyde, vulcanized rubber, melamine resin, polyimide, epoxy novolac resin, cyanate ester, silicone resin, and acrylic resin

The curing agent may include one of aliphatic amine, aromatic amine, cycloaliphatic amine, phenalkamine, imidazole, carboxylic acid, anhydride, polyamide-based hardners, phenolic curing agents, and waterborne curing agents.

The solder particles 55 may include one of tin (Sn), indium (In), and zinc (Zn). Specifically, the solder particles 55 may include one of SnCu, SnZn, SnBi, SnAgCu, SnAg, AuSn, In, InSn, and BilnSn. Each of the solder particles 55 may have a diameter of about 100 nm to about 100 μm.

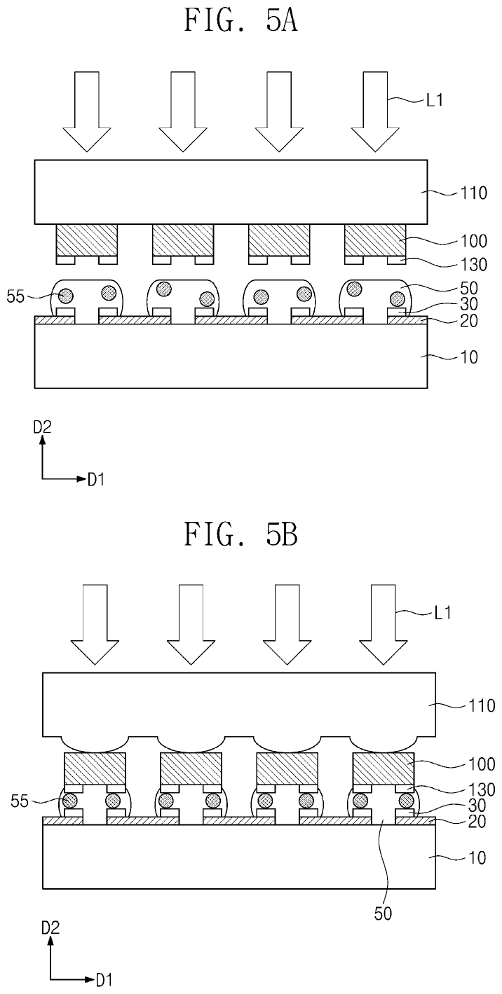

Referring to FIGS. 1 and 4, a transfer tape 110 may be spaced upward from the bonding part 50 in a second direction D2 in the process S300. A bonding target object 100 may be disposed adjacent to a bottom surface of the transfer tape 110. The bonding target object 100 may be provided in plurality. The bonding target objects 100 may be spaced apart from each other in the first direction D1. A pad 130 may be disposed on a bottom surface of each of the bonding target objects 100. The pad 130 may be provided in plurality. The pads 130 may be spaced apart from each other in the first direction D1.

The transfer tape 110 may be disposed on the substrate 10 so that the bonding part 50 faces the bonding target object 100.

Specifically, the transfer tape 110 may be disposed on the substrate 10 so that the pads 30 of the substrate 10 face the pads 130 of the bonding target object 100, respectively.

The transfer tape 110 may include a material that swells when irradiated with a laser or heated. Specifically, the transfer tape 110 may include one of poly(methyl methacrylate)(PMMA), poly(N-vinylcarbazole), gelatin films, PEN, PET, PTFE (Teflon), and polyimide.

The bonding target object 100 may be a package, a semiconductor device, a display device, a sensor device, or a communication device. The bonding target object 100 may include a semiconductor chip (not shown).

Each of the pads 130 of the bonding target object 100 may include a conductive material. Specifically, each of the pads 130 of the bonding target object 100 may include copper (Cu) or aluminum (Al).

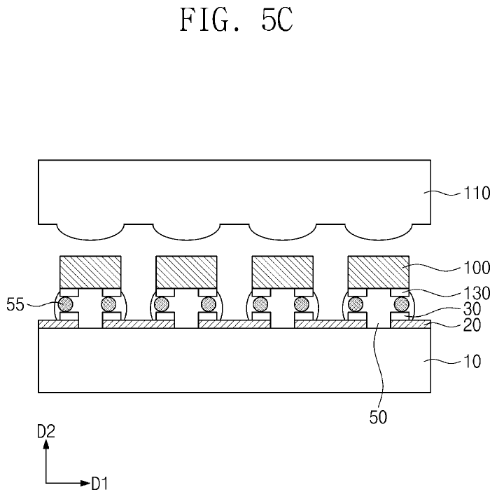

FIGS. 5A, 5B, and 5C are process views illustrating each process of transferring the bonding target object to the substrate according to an embodiment of the inventive concept.

Referring to FIGS. 1, 5A, 5B, and 5C, the bonding target object 100 may be transferred to the substrate 10 by irradiating the top surface of the transfer tape 110 with a first laser L1 in the process S400.

Specifically, referring to FIG. 5A, a first laser source generating the first laser L1 may be spaced apart from the bonding target object 100 in the second direction D2 perpendicular to the first direction D1. The first laser source generating the first laser L1 may be spaced apart from the bonding target object 100 so that the transfer tape 110 is disposed between the first laser L1 and the bonding target object 100. The first laser sources may be spaced apart from each other in the first direction D1 to correspond to the bonding target objects 100 spaced apart from each other in the first direction D1. When the top surface of the transfer tape 110 is irradiate with the first laser L1, an area on which the bonding target object 100 is disposed is irradiated with the first laser L1.

A portion of the transfer tape 110, which is irradiated with the first laser L1, may increase in temperature. Referring to FIG. 5B, one surface of the transfer tape 110, which is adjacent to the bonding target object 100, may swell by the first laser L1. Thus, a surface area in which the transfer tape 110 contacts the bonding target object 100 may decrease. As the surface area in which the transfer tape 110 contacts the bonding target object 100 decreases, an adhesive force between the transfer tape 110 and the bonding target object 100 may decrease. As the one surface of the transfer tape 110 swells, the pad 130 disposed on a bottom surface of the bonding target object 100 may contact the pad 30 disposed on a top surface of the substrate 10. Thus, an adhesive force between the pad 130 disposed on the bottom surface of the bonding target object 100 and the bonding part 50 may increase.

Referring to FIG. 5C, as the adhesive force between the transfer tape 110 and the bonding target object 100 decreases, and the adhesive force between the pad 130 disposed on the bottom surface of the bonding target object 100 and the bonding part 50 increases, the bonding target object 100 may be separated from the transfer tape 110 and transferred onto the substrate 10.

The first laser L1 may be an ultraviolet (UV) laser or an infrared ray (IR) laser. The first laser L1 may have a wavelength of about 100 nm to about 10 μm. The first laser L1 may be a continuous wave (CW) or a pulse.

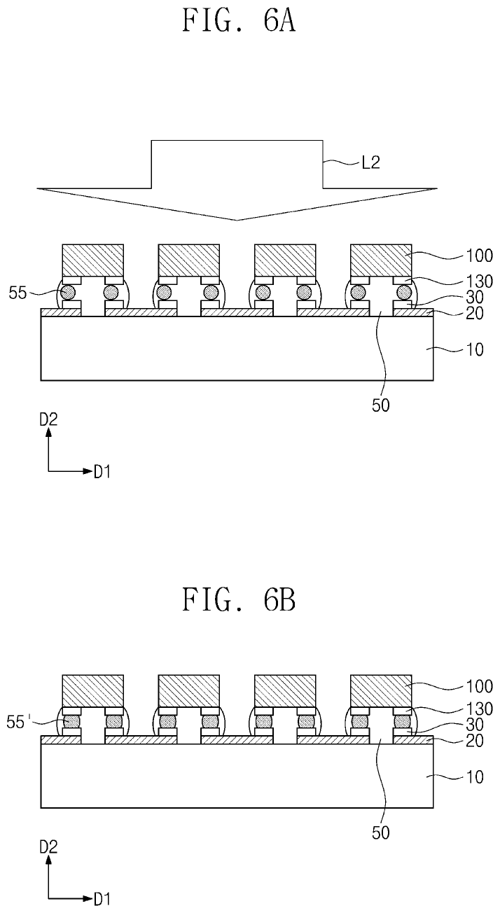

FIGS. 6A and 6B are process views illustrating each process of bonding the bonding part with the bonding target object according to an embodiment of the inventive concept.

Referring to FIGS. 1, 6A, and 6B, as the top surface of the substrate 10 is irradiated with a second laser L2, the pad 130 of the bonding target object 100 may be electrically connected to the pad 30 of the substrate 10 in the process S500.

Specifically, referring to FIG. 6A, a second laser source generating the second laser L2 may be spaced apart from the bonding target object 100 in the second direction D2.

The bonding target object 100 may increase in temperature by light emitted from the second laser source, and as heat is transferred to the bonding part 50, the bonding part 50 may also increase in temperature. Thus, the solder particles 55 in the bonding part 50 may increase in temperature, and an oxide layer of the solder particles 55 may be removed by the reducing agent in the bonding part 50. Referring to FIG. 6B, as the oxide layer is removed, an upper portion of each of the solder particles 55′ may be bonded to the pad 130 of the bonding target object 100, and a lower portion of each of the solder particles 55′ may be bonded to the pad 30 of the substrate 10. Specifically, the upper portion of the solder particle 55′ and the pad 130 of the bonding target object 100 may form an intermetallic compound, and the lower portion of the solder particle 55′ and the pad 30 of the substrate 10 may form an intermetallic compound. Thus, the pad 130 of the bonding target object 100 may be electrically connected to the pad 30 of the substrate 10 by the solder particle 55′.

For example, the second laser L2 may be an IR laser. The second laser L2 may have a wavelength of about 100 nm to about 10 μm. The second laser L2 may be a continuous wave (CW) or a pulse.

The transfer and bonding method according to an embodiment of the inventive concept may further include a process of curing the bonding part 50 and the bonding target object 100 after bonded to each other.

According to the embodiments of the present invention, the process order is not limited to the above order. According to some embodiments, the process S400 of transferring the bonding target object on the bonding part by irradiating the top surface of the transfer tape with the first laser, and the process S500 of bonding the bonding part with the bonding target object by irradiating the top surface of the bonding target object with the second laser may be performed in an order opposite to the described order. Specifically, the process S500 of bonding the bonding part with the bonding target object by irradiating the top surface of the bonding target object with the second laser may be performed before the process S400 of transferring the bonding target object on the bonding part by irradiating a top surface of the transfer tape with a first laser.

The process S400 of transferring the bonding target object on the bonding part by irradiating the top surface of the transfer tape with the first laser may include irradiating the top surface of the transfer tape with the first laser, and removing the transfer tape. According to some embodiments, the process S500 of bonding the bonding part with the bonding target object by irradiating the top surface of the bonding target object with the second laser may be performed after the irradiating the top surface of the transfer tape with the first laser, and before the removing the transfer tape.

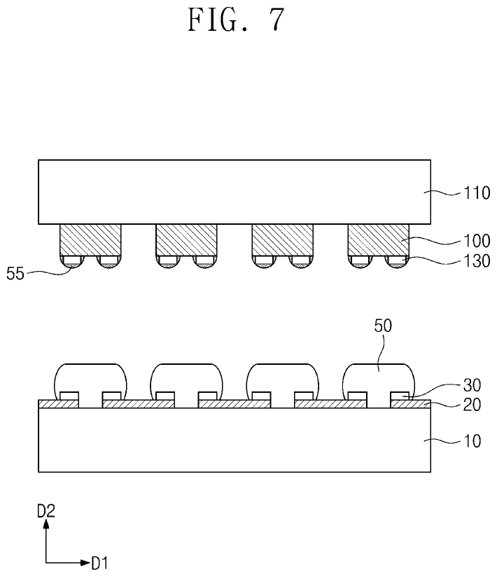

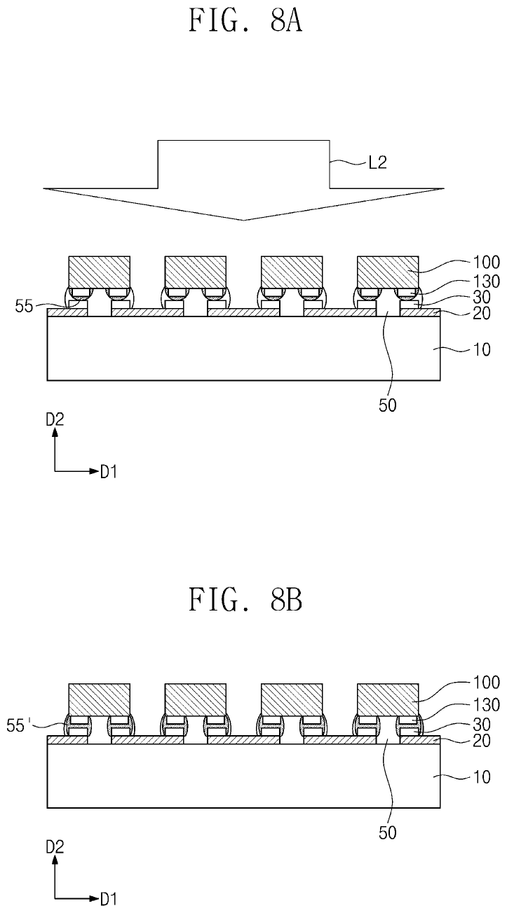

FIGS. 7, 8A, and 8B are process views illustrating a transfer and bonding method according to a modified embodiment of the inventive concept.

First, as described with reference to FIGS. 1 to 3, a pattern 20 may be disposed on a top surface of a substrate 10, and a plurality of pads 30 may be disposed on a top surface of the pattern 20. The pads 30 may be spaced apart from each other in the first direction D1. A bonding part 50 may be formed on the substrate 10 in the process S200. The bonding part 50 may be formed on a portion or a whole of the top surface of the substrate 10. Specifically, the bonding part 50 may be formed on a portion on the substrate 10, to which a bonding target object is bonded.

According to some embodiments, the solder particles 55 may not be provided in the bonding part 50 unlike FIGS. 1 to 3. Specifically, a solder ball 55 may be disposed on a surface of the pad 30 disposed on the substrate 10. The solder ball 55 may be provided in plurality. Specifically, the number of the solder balls 55 may be equal to that of the pads 30 of the substrate 10.

The transfer and bonding method according to a modified embodiment may be substantially the same as the transfer and bonding method described with reference to FIGS. 1 to 3 except that the solder ball 55 is disposed on a surface of a pad 130 of a bonding target object 100.

Referring to FIGS. 1 and 7, a transfer tape 110 may be spaced upward from the bonding part 50 in the second direction D2 in the process S300. A plurality of bonding target objects 100 may be disposed adjacent to a bottom surface of the transfer tape 110. The bonding target objects 100 may be spaced apart from each other in the first direction D1. A plurality of pads 130 may be disposed on a bottom surface of each of the bonding target objects 100. The pads 130 may be spaced apart from each other in the first direction D1.

The solder ball 55 may be disposed on a surface of each of the pads 130 of the bonding target object 100. The solder ball 55 may be provided in plurality. Specifically, the number of the solder balls 55 may be equal to that of the pads 30 of the substrate 10.

The transfer tape 110 may be disposed on the substrate 10 so that the bonding part 50 faces the bonding target object 100. Specifically, the transfer tape 110 may be disposed on the substrate 10 so that the pads 30 of the substrate 10 face the pads 130 of the bonding target object 100, respectively.

Thereafter, as described with reference to FIGS. 5A, 5B, and 5C, the bonding target object 100 may be transferred to the substrate 10 by irradiating a top surface of the transfer tape 110 with a first laser L1 in the process S400.

The bonding target object 100 may be transferred onto the substrate 10 by the substantially same method as the transfer and bonding method described with reference to FIGS. 5A, 5B, and 5C except that the solder ball 55 is disposed on the surface of the pad 130 of the bonding target object 100.

Thereafter, referring to FIGS. 1, 8A, and 8B, as the top surface of the substrate 10 is irradiated with a second laser L2, the pad 130 of the bonding target object 100 may be electrically connected to the pad 30 of the substrate 10 in the process S500.

Referring to FIG. 8A, the bonding target object 100 may increase in temperature by light emitted from a second laser source, and as heat is transferred to the bonding part 50, the bonding part 50 may also increase in temperature. Thus, a temperature of the solder ball 55 disposed on the surface of the pad 130 of the bonding target object 100 may increase, and an oxide layer of the solder ball 55 may be removed. Referring to FIG. 8B, as the oxide layer is removed, a lower portion of the solder ball 55′ may be bonded to the pad 30 of the substrate 10. Specifically, the lower portion of the solder ball 55′ and the pad 30 of the substrate 10 may form an intermetallic compound. Thus, the pad 130 of the bonding target object 100 may be electrically connected to the pad 30 of the substrate 10 by the solder ball 55′.

The transfer and bonding method according to another embodiment of the inventive concept is substantially the same as the transfer and bonding method described with reference to FIGS. 1 to 4, 5A, 5B, 5C, 6A, and 6B except that the solder ball 55 is disposed on the surface of the pad 130 of the bonding target object 100 instead of the solder particles 55 being contained in the bonding part 50.

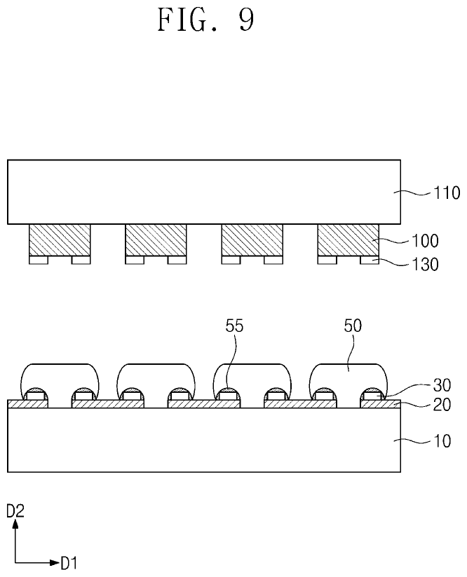

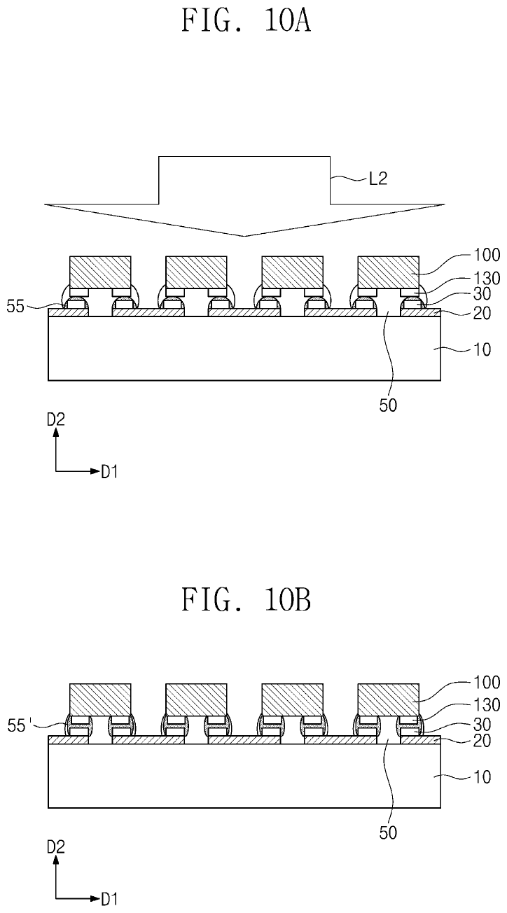

FIGS. 9, 10A, and 10B are process views illustrating a transfer and bonding method according to another modified embodiment of the inventive concept.

First, as described with reference to FIGS. 1 to 3, a pattern 20 may be disposed on a top surface of a substrate 10, and a plurality of pads 30 may be disposed on a top surface of the pattern 20. The pads 30 may be spaced apart from each other in the first direction D1. A bonding part 50 may be formed on the substrate 10 in the process S200. The bonding part 50 may be formed on a portion or a whole of the top surface of the substrate 10. Specifically, the bonding part 50 may be formed on a portion on the substrate 10, to which a bonding target object is bonded.

According to some embodiments, the solder particles 55 may not be provided in the bonding part 50 unlike FIGS. 1 to 3. Specifically, a solder ball 55 may be disposed on a surface of the pad 30 disposed on the substrate 10. The solder ball 55 may be provided in plurality. Specifically, the number of the solder balls 55 may be equal to that of the pads 30 of the substrate 10.

The transfer and bonding method according to another embodiment may be substantially the same as the transfer and bonding method described with reference to FIGS. 1 to 3 except that the solder ball 55 is disposed on the surface of the pad 30 of the substrate 10.

Referring to FIGS. 1 and 9, a transfer tape 110 may be spaced upward from the bonding part 50 in the second direction D2 in the process S300. A plurality of bonding target objects 100 may be disposed adjacent to a bottom surface of the transfer tape 110. The bonding target objects 100 may be spaced apart from each other in the first direction D1. A plurality of pads 130 may be disposed on a bottom surface of each of the bonding target objects 100. The pads 130 may be spaced apart from each other in the first direction D1. The substrate 10 may include the solder ball 55 disposed on the surface of the pad 30 of the substrate 10. Specifically, the solder ball 55 may be disposed on the surface of the pad 30 disposed on the substrate 10.

The transfer tape 110 may be disposed on the substrate 10 so that the bonding part 50 faces the bonding target object 100. Specifically, the transfer tape 110 may be disposed on the substrate 10 so that the pads 30 of the substrate 10 face the pads 130 of the bonding target object 100, respectively.

Thereafter, as described with reference to FIGS. 5A, 5B, and 5C, the bonding target object 100 may be transferred to the substrate 10 by irradiating a top surface of the transfer tape 110 with a first laser L1 in the process S400.

The bonding target object 100 may be transferred onto the substrate 10 by the substantially same method as the transfer and bonding method described with reference to FIGS. 5A, 5B, and 5C except that the solder ball 55 is disposed on the surface of the pad 30 of the substrate 100.

Thereafter, referring to FIGS. 1, 10A, and 10B, as the top surface of the substrate 10 is irradiated with a second laser L2, the pad 130 of the bonding target object 100 may be electrically connected to the pad 30 of the substrate 10 in the process S500.

Referring to FIG. 10A, the bonding target object 100 may increase in temperature by light emitted from a second laser source, and as heat is transferred to the bonding part 50, the bonding part 50 may also increase in temperature. Thus, a temperature of the solder ball 55 disposed on the surface of the pad 30 of the substrate 10 may increase, and an oxide layer of the solder ball 55 may be removed. Referring to FIG. 10B, as the oxide layer is removed, an upper portion of the solder ball 55′ may be bonded to the pad 130 of the bonding target object 100. Specifically, the upper portion of the solder ball 55′ and the pad 130 of the bonding target object 100 may form an intermetallic compound. Thus, the pad 130 of the bonding target object 100 may be electrically connected to the pad 30 of the substrate 10 by the solder ball 55′.

The transfer and bonding method according to another embodiment of the inventive concept is substantially the same as the transfer and bonding method described with reference to FIGS. 1 to 4, 5A, 5B, 5C, 6A, and 6B except that the solder ball 55 is disposed on the surface of the pad 30 of the substrate 10 instead of the solder particles 55 being contained in the bonding part 50.

Since the laser is used, the bonding process may be performed at a relatively low temperature by the laser bonding method according to the embodiments of the inventive concept. Also, a component disposed at a lower portion, e.g., the substrate, may be unnecessary to be heated. Thus, a solder having a melting point of a low temperature may be used. Thus, the substrate and the bonding target object may not be heated at a high temperature. Therefore, a warpage phenomenon generated by difference in coefficient of expansion (COE) of the substrate and/or the bonding target object may be prevented. Also, the substrate and/or the bonding target object may be prevented from being damaged at a high temperature. Thus, a component having a further small thickness may be used, and an organic material that is vulnerable to heat may be also used. Also, as the plurality of bonding target objects are simultaneously transferred onto the substrate from the transfer tape by irradiating the top surface of the transfer tape with the first laser, and the bonding target objects are simultaneously bonded to the pads of the substrate by irradiating the top surface of the object to be bonded with the second laser, a process speed may be maximized to improve a process yield and reduce a manufacturing cost.

The transfer and bonding method using the laser according to the embodiments of the inventive concept may extremely maximize the speed of the transfer and bonding process because the plurality of devices or packages are simultaneously transferred onto the substrate from the transfer tape by irradiating the top surface of the transfer tape with the first laser, and the plurality of transferred devices or packages are simultaneously bonded to the pads of the substrate by irradiating the top surface of the devices or packages with the second laser.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed. Therefore, the embodiments described above include exemplary in all respects and not restrictive, but it should be understood.

What is claimed is:

1. A transfer and bonding method using a laser, comprising:
providing a substrate comprising a pad;
forming a bonding part on the substrate to cover the pad;
aligning a transfer tape comprising an object to be bonded on the boding part;
transferring the object to be bonded onto the bonding part by irradiating a top surface of the transfer tape with a first laser; and
bonding the bonding part with the object to be bonded by irradiating a top surface of the object to be bonded with a second laser.

2. The transfer and bonding method of claim 1, wherein the bonding part comprises solder particles.

3. The transfer and bonding method of claim 2, wherein the bonding of the bonding part with the object to be bonded comprises:
bonding an upper portion of each of the solder particles with a pad of the object to be bonded; and
bonding a lower portion of each of the solder particles with a pad of the substrate.

4. The transfer and bonding method of claim 3, wherein the bonding of the upper portion of each of the solder particles with the pad of the object to be bonded comprises forming an intermetallic compound by the upper portion of the solder particle and the pad of the object to be bonded, and
the bonding of the lower portion of each of the solder particles with the pad of the substrate comprises forming an intermetallic compound by the lower portion of the solder particle and the pad of the substrate.

5. The transfer and bonding method of claim 2, wherein the bonding of the bonding part with the object to be bonded comprises removing an oxide layer of each of the solder particles by irradiating the object to be bonded with the second laser.

6. The transfer and bonding method of claim 1, wherein one area of the transfer tape, which overlaps the object to be bonded, is irradiated with the first laser, and
a top surface of the substrate, to which the object to be bonded is transferred, is irradiated with the second laser.

7. The transfer and bonding method of claim 1, wherein the transferring of the object to be bonded comprises reducing a contact area between the transfer tape and the object to be bonded by irradiating the transfer tape with the first laser so that one surface of the transfer tape, which is adjacent to the object to be bonded, swells.

8. The transfer and bonding method of claim 1, wherein the bonding of the bonding part with the object to be bonded comprises electrically connecting a pad of the object to be bonded and the pad of the substrate.

9. The transfer and bonding method of claim 1, wherein the bonding part comprises one of a polymer material, a reducing agent, and a curing agent.

10. The transfer and bonding method of claim 9, wherein the polymer material comprises one of epoxy resin, phenoxy resin, bismaleimide, unsaturated polyester, urethane, urea, phenol-formaldehyde, vulcanized rubber, melamine resin, polyimide, epoxy novolac resin, cyanate ester, silicone resin, and acrylic resin.

11. The transfer and bonding method of claim 9, wherein the curing agent comprises one of aliphatic amine, aromatic amine, cycloaliphatic amine, phenalkamine, imidazole, carboxylic acid, anhydride, polyamide-based hardners, phenolic curing agents, and waterborne curing agents.

12. The transfer and bonding method of claim 1, wherein the transfer tape comprises one of poly(methyl methacrylate)(PMMA), poly(N-vinylcarbazole), gelatin films, PEN, PET, PTFE (Teflon), and polyimide.

13. The transfer and bonding method of claim 1, further comprising curing the bonding part and the object to be bonded after bonded to each other.

14. The transfer and bonding method of claim 1, wherein the bonding the bonding part with the object to be bonded by irradiating the top surface of the object to be bonded with the second laser is performed before the transferring the object to be bonded onto the bonding part by irradiating the top surface of the transfer tape with the first laser.

15. The transfer and bonding method of claim 1, wherein the transferring the object to be bonded onto the bonding part by irradiating the top surface of the transfer tape with the first laser comprises:
irradiating the top surface of the transfer tape with the first laser; and
removing the transfer tape, and
wherein the bonding the bonding part with the object to be bonded by irradiating the top surface of the object to be bonded with the second laser is performed after the irradiating the top surface of the transfer tape with the first laser, and before the removing the transfer tape.

16. A transfer and bonding method using a laser, comprising:
providing a substrate comprising a pad;
forming a bonding part on the substrate to cover the pad;
aligning a transfer tape comprising an object to be bonded on the boding part;
transferring the object to be bonded onto the bonding part by irradiating a top surface of the transfer tape with a first laser; and
bonding the bonding part with the object to be bonded by irradiating a top surface of the bonding part with a second laser,
wherein a pad of the object to be bonded or the pad disposed on the substrate comprises a solder formed thereon, and
wherein the bonding of the bonding part with the object to be bonded comprises removing an oxide layer of each of the solder particles by irradiating the solder particles with the second laser.

17. The transfer and bonding method of claim 16, wherein the transferring of the object to be bonded comprises reducing a contact area between the transfer tape and the object to be bonded by irradiating the transfer tape with the first laser so that one surface of the transfer tape, which is adjacent to the object to be bonded, swells.

18. The transfer and bonding method of claim 16, wherein one area of the transfer tape, which overlaps the object to be bonded, is irradiated with the first laser, and
a top surface of the substrate, to which the object to be bonded is transferred, is irradiated with the second laser.
